(19) United States
(12) Patent Application Publication
(10) Pub. No.: US 2025/0234627 A1
(43) Pub. Date: Jul. 17, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Shotaro Baba, Kawasaki Kanagawa (JP); Tomoaki Inokuchi, Yokohama Kanagawa (JP); Tatsuo Shimizu, Shinagawa Tokyo (JP); Tatsuya Nishiwaki, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/004,622

(22) Filed: Dec. 30, 2024

(30) Foreign Application Priority Data
Jan. 11, 2024 (JP) 2024-002834

(51) Int. Cl. H10D 64/64; H10D 30/63; H10D 64/00; H10D 64/01; H10D 64/23

(52) U.S. Cl. CPC H10D 64/647; H10D 30/63; H10D 64/01; H10D 64/2527; H10D 64/117

(57) ABSTRACT

A semiconductor device includes a first electrode, a first conductive part, a semiconductor part, a second conductive part, a gate electrode and an insulating part. The first conductive part includes at least one of a metal, a metal oxide, or a metal nitride. The at least one of the metal, the metal oxide, or the metal nitride includes at least one selected from the group consisting of Ti, Ta, W, Cr, and Ru. The semiconductor part includes a first semiconductor region and a second semiconductor region. The first conductive part has a Schottky contact with the first semiconductor region. The second conductive part has a Schottky contact with the second semiconductor region. The second conductive part includes at least one selected from the group consisting of Pt, Ni, Ir, Pd, Au, and Co.

### CROSS-REFERENCE TO RELATED APPLICATIONS

This application is based upon and claims the benefit of priority from Japanese Patent Application No. 2024-002834, filed on Jan. 11, 2024; the entire contents of which are incorporated herein by reference.

### FIELD

Embodiments relate to a semiconductor device.

### BACKGROUND

There is a semiconductor device that includes a body diode.

### BRIEF DESCRIPTION OF THE DRAWINGS

FIG. 1 is a schematic cross-sectional view illustrating a semiconductor device according to an embodiment;

FIG. 2 is a schematic cross-sectional view illustrating the semiconductor device according to the embodiment;

FIGS. 3A and 3B are schematic cross-sectional views illustrating a method for manufacturing the semiconductor device according to the embodiment;

FIGS. 4A and 4B are schematic cross-sectional views illustrating the method for manufacturing the semiconductor device according to the embodiment;

FIG. 5 is a schematic cross-sectional view illustrating a semiconductor device according to an embodiment;

FIG. 6 is a schematic cross-sectional view illustrating the semiconductor device according to the embodiment;

FIGS. 7A and 7B are schematic cross-sectional views illustrating a method for manufacturing the semiconductor device according to the embodiment; and

FIGS. 8A and 8B are schematic cross-sectional views illustrating the method for manufacturing the semiconductor device according to the embodiment.

### DETAILED DESCRIPTION

A semiconductor device according to one embodiment, includes a first electrode, a first conductive part, a semiconductor part, a second conductive part, a gate electrode and an insulating part. A direction from the first electrode toward the first conductive part is along a first direction. The first conductive part includes at least one of a metal, a metal oxide, or a metal nitride. The at least one of the metal, the metal oxide, or the metal nitride includes at least one selected from the group consisting of Ti, Ta, W, Cr, and Ru. The semiconductor part is of a first conductivity type. The semiconductor part includes a first semiconductor region and a second semiconductor region. At least a portion of the first semiconductor region is positioned between the first conductive part and the first electrode. The first conductive part has a Schottky contact with the first semiconductor region. A direction from the first conductive part toward the second semiconductor region is along a second direction crossing the first direction. The second conductive part has a Schottky contact with the second semiconductor region. The second conductive part includes at least one selected from the group consisting of Pt, Ni, Ir, Pd, Au, and Co. At least a portion of the second conductive part is positioned between the first conductive part and the second semiconductor region. At least a portion of the second semiconductor region is positioned between the gate electrode and the second conductive part. The insulating part includes a first insulating region. The first insulating region is located between the gate electrode and the second semiconductor region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

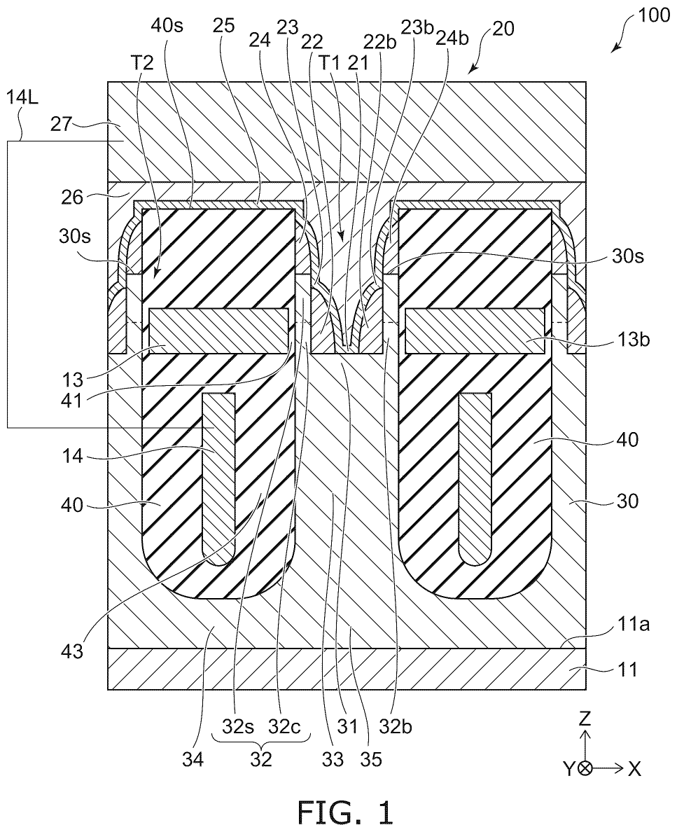

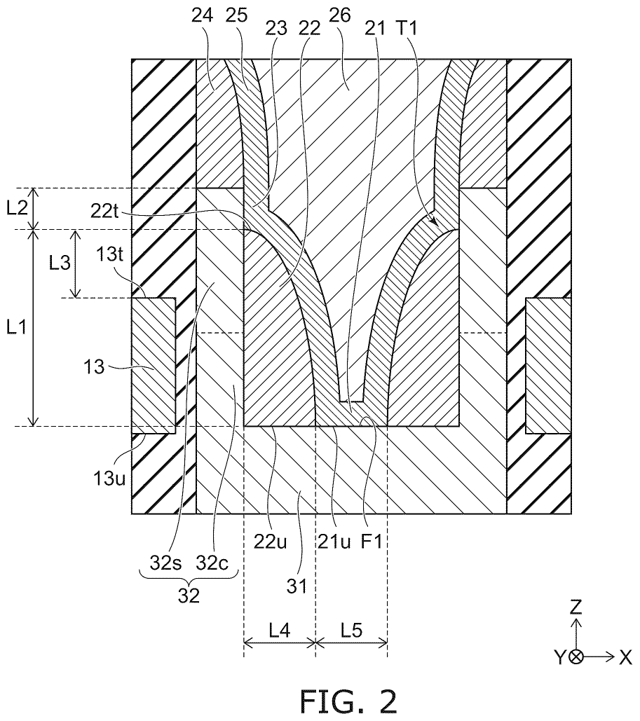

FIGS. 1 and 2 are schematic cross-sectional views illustrating a semiconductor device according to an embodiment.

FIG. 2 is an enlarged illustration of the periphery of a first conductive part 21 of FIG. 1.

As illustrated in FIG. 1, the semiconductor device 100 according to the embodiment includes a first electrode 11, a second electrode 20, a gate electrode 13, an insulating part 40, and a semiconductor part 30. The second electrode 20 includes at least the first conductive part 21 and a second conductive part 22. The second electrode 20 also may include a third conductive part 23, a fourth conductive part 24, a conductive layer 26, and a conductive layer 27.

The direction from the first electrode 11 toward the first conductive part 21 is along a first direction. In the description of embodiments, the first direction is taken as a Z-direction. A direction crossing the first direction is taken as a second direction (an X-direction). The X-direction may be perpendicular to the Z-direction. A direction crossing the first and second directions is taken as a third direction (a Y-direction). The Y-direction may be perpendicular to the Z-direction and X-direction. For example, the Z-direction is perpendicular to an upper surface 11a of the first electrode 11 contacting the semiconductor part 30. For example, a surface 30s of the semiconductor part 30 (a major surface of a semiconductor substrate) extends along the X-Y plane perpendicular to the Z-direction. The surface 30s is positioned at the second electrode 20 side of the semiconductor part 30 in the Z-direction. The positional relationship or direction in the Z-direction from the first electrode 11 toward the second electrode 20 may be called “up”.

The direction from the first electrode 11 toward the semiconductor part 30 is along the first direction. The semiconductor part 30 includes a first semiconductor region 31, a second semiconductor region 32, a third semiconductor region 33, a fourth semiconductor region 34, and a fifth semiconductor region 35. The semiconductor part 30 (the first to fifth semiconductor regions) is of a first conductivity type. In the example, the first conductivity type is an n-type; and a second conductivity type is a p-type; however, according to the embodiment, the first conductivity type may be the p-type; and the second conductivity type may be the n-type.

At least a portion of the first semiconductor region 31 is positioned between the first conductive part 21 and the first electrode 11. The direction from the first semiconductor region 31 toward the first conductive part 21 is along the Z-direction.

At least a portion of the second semiconductor region 32 is arranged with the first conductive part 21 in the X-direction. In other words, the direction from the first conductive part 21 toward the second semiconductor region 32 is along the X-direction. The second semiconductor region 32 may be separated from the first conductive part 21 in the X-direction.

For example, a trench T1 is provided in the surface 30s of the semiconductor part 30. The trench T1 is a recess that is concave downward (in the direction of the first electrode 11). For example, the trench T1 extends in the Y-direction. Multiple trenches T1 may be arranged in the X-direction with a spacing interposed. The first semiconductor region 31 forms the bottom surface of the trench T1. The second semiconductor region 32 forms the side surface of the trench T1.

The second semiconductor region 32 may include a first region 32s and a second region 32c. The second region 32c is positioned between the first region 32s and the first electrode 11. The first-conductivity-type impurity concentration (atoms/cm³) in the first region 32s is greater than the first-conductivity-type impurity concentration in the second region 32c.

The third semiconductor region 33 is positioned between the first electrode 11 and the first semiconductor region 31 in the Z-direction. The fourth semiconductor region 34 is positioned between the first electrode 11 and the insulating part 40 in the Z-direction. The fifth semiconductor region 35 is positioned between the third semiconductor region 33 and the first electrode 11 in the Z-direction, and is arranged with the fourth semiconductor region 34 in the X-direction. The fourth semiconductor region 34 and the fifth semiconductor region 35 contact the first electrode 11. The semiconductor part 30 is electrically connected with the first electrode 11 at the fourth and fifth semiconductor regions 34 and 35.

The first conductive part 21, the second conductive part 22, and the third conductive part 23 are located inside the trench T1. The second electrode 20 is electrically connected with the semiconductor part 30 at the portions (the first conductive part 21, the second conductive part 22, and the third conductive part 23) located inside the trench T1.

The first conductive part 21 contacts the bottom of the trench T1. In other words, the first conductive part 21 contacts the first semiconductor region 31. The first conductive part 21 is electrically connected with the first semiconductor region 31. The first conductive part 21 has a Schottky contact with the first semiconductor region 31. The first conductive part 21 may not contact the side surface of the trench T1. In other words, the first conductive part 21 may not contact the second semiconductor region 32 in the X-direction. In the example, the first conductive part 21 is a portion of a conductive layer 25 (a conductive film) included in the second electrode 20.

At least a portion of the second conductive part 22 is positioned between the first conductive part 21 and the second semiconductor region 32. The X-direction position of the second conductive part 22 is between the X-direction position of the first conductive part 21 and the X-direction position of the second semiconductor region 32.

The second conductive part 22 contacts the side surface of the trench T1 in the X-direction. In other words, the second conductive part 22 contacts the second semiconductor region 32. The second conductive part 22 is arranged with the second semiconductor region 32 in the X-direction. In other words, the direction from the second conductive part 22 toward the second semiconductor region 32 (the first region 32s and the second region 32c) is along the X-direction. The second conductive part 22 has a Schottky contact with the second semiconductor region 32 (the second region 32c). The second conductive part 22 contacts the first conductive part 21 in the X-direction and is electrically connected with the first conductive part 21.

The second conductive part 22 is located on a portion of the first semiconductor region 31. In other words, the portion of the first semiconductor region 31 is positioned between the second conductive part 22 and the first electrode 11. The second conductive part 22 contacts the bottom of the trench T1. That is, the second conductive part 22 contacts the portion of the first semiconductor region 31. For example, the second conductive part 22 has a Schottky contact with the portion of the first semiconductor region 31.

The third conductive part 23 is positioned above the second conductive part 22. In other words, the second conductive part 22 is positioned between the third conductive part 23 and the first semiconductor region 31 in the Z-direction. The direction from the second conductive part 22 toward the third conductive part 23 is along the Z-direction. The third conductive part 23 contacts the upper end of the second conductive part 22. The third conductive part 23 is electrically connected with the second conductive part 22.

The third conductive part 23 contacts the side surface of the trench T1. In other words, the third conductive part 23 contacts the second semiconductor region 32. The third conductive part 23 is arranged with the second semiconductor region 32 in the X-direction. In other words, the direction from the third conductive part 23 toward the second semiconductor region 32 (the first region 32s) is along the X-direction.

In the example, the third conductive part 23 is a portion of the conductive layer 25. For example, the first conductive part 21 and the third conductive part 23 are formed of substantially the same material and are included in one continuous conductive layer 25.

The direction from the second conductive part 22 toward the gate electrode 13 is along the X-direction. At least a portion of the second semiconductor region 32 is positioned between the gate electrode 13 and the second conductive part 22.

As illustrated in FIG. 1, the semiconductor device 100 also includes a conductive part 14 (a conductive region). The direction from the conductive part 14 toward the third semiconductor region 33 is along the X-direction. In the example, the direction from the conductive part 14 toward the gate electrode 13 is along the Z-direction. The conductive part 14 is located between the gate electrode 13 and the first electrode 11. The fourth semiconductor region 34 is located between the conductive part 14 and the first electrode 11.

The insulating part 40 contacts the gate electrode 13, the conductive part 14, and the semiconductor part 30. The insulating part 40 electrically insulates the gate electrode 13 and the semiconductor part 30. The insulating part 40 electrically insulates the conductive part 14 and the semiconductor part 30. The insulating part 40 electrically insulates the gate electrode 13 and the conductive part 14.

More specifically, the insulating part 40 includes a first insulating region 41 located between the second semiconductor region 32 and the gate electrode 13. The insulating part 40 also includes a third insulating region 43 located between the third semiconductor region 33 and the conductive part 14. The insulating part 40 also includes a portion located between the fourth semiconductor region 34 and the conductive part 14, a portion located between the conductive part 14 and the gate electrode 13, and a portion located between the gate electrode 13 and the conductive layer 25.

For example, as illustrated in FIG. 1, a trench T2 is provided in the surface 30s of the semiconductor part 30. The trench T2 is a recess that is concave downward. For example, the trench T2 extends in the Y-direction. Multiple trenches T2 may be arranged in the X-direction with a spacing interposed. The trench T1 and the trench T2 are alternately arranged in the X-direction. At least a portion of the insulating part 40 is located inside the trench T2. The gate electrode 13 and the conductive part 14 are surrounded with the insulating part 40 inside the trench T2.

The insulating part 40 includes an end surface 40s (an upper surface) in the Z-direction. The gate electrode 13 is positioned between the end surface 40s and the first electrode 11. In the example, the end surface 40s of the insulating part 40 is positioned higher than the semiconductor part 30. In other words, the Z-direction position of the semiconductor part 30 is between the Z-direction position of the end surface 40s of the insulating part 40 and the Z-direction position of the first electrode 11.

The conductive layer 25 is located on the insulating part 40, the semiconductor part 30, and the second conductive part 22. In other words, the insulating part 40, the semiconductor part 30, and the second conductive part 22 are positioned between the conductive layer 25 and the first electrode 11. The conductive layer 25 contacts the semiconductor part 30 and the second conductive part 22 and is electrically connected with the semiconductor part 30 and the second conductive part 22. The conductive layer 25 contacts the end surface 40s of the insulating part 40.

The conductive layer 26 is stacked on the conductive layer 25. In other words, the conductive layer 25 is positioned between the conductive layer 26 and the first electrode 11. The conductive layer 26 contacts the conductive layer 25, and is electrically connected with the conductive layer 25. A portion of the conductive layer 26 is located inside the trench T1. Another portion of the conductive layer 26 is located above the insulating part 40. In other words, the direction from the insulating part 40 toward the other portion of the conductive layer 26 is along the Z-direction.

The conductive layer 27 is stacked on the conductive layer 26. In other words, the conductive layer 26 is positioned between the conductive layer 27 and the first electrode 11. The conductive layer 27 contacts the conductive layer 26 and is electrically connected with the conductive layer 26.

The semiconductor device 100 is, for example, a MOSFET (Metal Oxide Silicon Field Effect Transistor). The current that flows between the first electrode 11 and the second electrode 20 can be controlled by controlling the potential of the gate electrode 13. For example, the first electrode 11 functions as a drain electrode. For example, the second electrode 20 functions as a source electrode. For example, the first region 32s of the second semiconductor region 32 functions as a source region. For example, the second region 32c of the second semiconductor region 32 functions as a channel region. For example, the first insulating region 41 functions as a gate insulating film.

For example, a Schottky barrier is formed at the interface between the second conductive part 22 and the second semiconductor region 32 (the second region 32c); and a depletion layer is formed in the second semiconductor region 32 (the second region 32c). The carrier concentration in the second semiconductor region 32 (the second region 32c) is controlled by the potential of the gate electrode 13 controlling the thickness (the X-direction distance) of the Schottky barrier. When the carrier concentration in the second semiconductor region 32 is low, substantially no current flows between the second electrode 20 and the first electrode 11 via the second semiconductor region 32. In other words, an off-state is obtained. When the potential of the gate electrode 13 is controlled to cause the carrier concentration in the second semiconductor region 32 to increase, a current flows between the second electrode 20 and the first electrode 11 via the second semiconductor region 32. In other words, an on-state is obtained. For example, carriers flow between the second electrode 20 and the semiconductor part 30 via the portions (the fourth conductive part 24, the third conductive part 23, and a portion of the second conductive part 22) of the second electrode 20 contacting the first region 32s.

For example, a Schottky barrier is formed at the interface between the first semiconductor region 31 and the first conductive part 21 (and the second conductive part 22). The thickness (the Z-direction distance) of the Schottky barrier can be controlled by the potential of the gate electrode 13. A current does not easily flow when the Schottky barrier is thick. For example, the off-state is obtained. By controlling the potential of the gate electrode 13, the Schottky barrier becomes thin, and the tunnel current flows more easily. For example, the on-state is obtained.

For example, the conductive part 14 is electrically connected with the second electrode 20. Or, the conductive part 14 may be electrically connectable with the second electrode 20. For example, as illustrated in FIG. 1, the semiconductor device 100 may include a wiring part 14L electrically connecting the conductive part 14 and the second electrode 20. The conductive part 14 and the second electrode 20 may be electrically connected via wiring parts and/or terminals outside the semiconductor device 100.

The potential of the conductive part 14 is set to the potential of the second electrode 20 (e.g., the source potential). By including the conductive part 14, the electric field of the semiconductor part 30 can be controlled. For example, local electric field concentration can be suppressed. For example, high reliability is easily obtained. For example, the conductive part 14 functions as a field plate.

For example, a transistor of a reference example has an n-p-n structure. In such a case, the gate length increases according to the width of the p-n junction. In contrast, according to the embodiment, the semiconductor part 30 is of the first conductivity type, and may not include a region of the second conductivity type. That is, a p-n junction is not formed. For example, the gate length is easily reduced thereby. Therefore, the gate capacitance is easily reduced. Also, for example, the on-resistance is easily reduced. Faster switching, turn-on loss suppression, and turn-off loss suppression can be realized. According to the embodiment, a semiconductor device can be provided in which the characteristics can be improved.

In the transistor of the reference example, a body diode is formed by a p-n junction. Therefore, there are cases where a long period of time is necessary for recovery. In contrast, according to the embodiment, a Schottky barrier is formed at the interface between the first conductive part 21 and the first semiconductor region 31. A body diode is formed thereby. Thus, recovery characteristics can be improved because the body diode is a Schottky barrier diode. The recovery can be faster. The forward voltage of the body diode can be reduced.

The first conductive part 21 is, for example, at least one of a metal, a metal oxide, or a metal nitride; and the at least one of the metal, the metal oxide, or the metal nitride includes at least one selected from the group consisting of Ti (titanium), Ta (tantalum), W (tungsten), Cr (chrome), and Ru (ruthenium). The first conductive part 21 includes, for example, a material having a relatively small work function.

In other words, the first conductive part 21 includes a first element. The first element is, for example, at least one selected from the group consisting of Ti, Ta, W, Cr, and Ru. The first conductive part 21 includes, for example, simple metals (e.g., Ti, Ta, W, Cr, Ru, etc.) included in the first element. The first conductive part 21 may include, for example, a compound including the first element. For example, the first conductive part 21 includes a nitride of the first element (e.g., titanium nitride, tantalum nitride, tungsten nitride, chromium nitride, ruthenium nitride, etc.). For example, the first conductive part 21 includes an oxide of the first element (e.g., titanium oxide, tantalum oxide, tungsten oxide, chromium oxide, ruthenium oxide, etc.). Or, the first conductive part 21 may include an alloy including the first element or a solid solution including the first element.

The second conductive part 22 includes, for example, at least one selected from the group consisting of Pt (platinum), Ni (nickel), Ir (iridium), Pd (palladium), Au (gold), and Co (cobalt). The first conductive part 21 includes, for example, a material having a relatively large work function.

In other words, the second conductive part 22 includes a second element. The second element is, for example, at least one selected from the group consisting of Pt, Ni, Ir, Pd, Au, and Co. The second conductive part 22 includes, for example, simple metals (e.g., Pt, Ni, Ir, Pd, Au, Co, etc.) included in the second element. The second conductive part 22 may include, for example, a compound, alloy, or solid solution including the second element.

The first conductive part 21, which includes a different material from the second conductive part 22 such as those described above, contacts the first semiconductor region 31. As a result, the height of the Schottky barrier between the first conductive part 21 and the semiconductor part 30 can be controlled, and the forward voltage of the body diode can be controlled. According to the embodiment, a more appropriate forward voltage of the body diode can be obtained.

In the example (in which the first conductivity type is the n-type), the work function of the first conductive part 21 may be less than the work function of the second conductive part 22. For example, the first conductive part 21 is made of a first conductive material having a lower work function than the second conductive part 22 (a second conductive material). For example, the second conductive part 22 is made of the second conductive material that has a higher work function than the first conductive part 21 (the first conductive material). In the example, for example, a low forward voltage of the body diode is obtained by the first conductive part 21, which has a lower work function than the second conductive part 22, contacting the bottom of the trench T1.

The second conductive part 22 contacts the second semiconductor region 32. As a result, the height of the Schottky barrier between the second semiconductor region 32 and the second conductive part 22 can be controlled, and the threshold of the transistor can be controlled. In the example (in which the first conductivity type is the n-type), the second conductive part 22 that has a higher work function than the first conductive part 21 contacts the side surface of the trench T1, and so, for example, the threshold can be prevented from becoming too low.

The third conductive part 23 is, for example, at least one of a metal, a metal oxide, or a metal nitride; and the at least one of the metal, the metal oxide, or the metal nitride includes at least one selected from the group consisting of Ti, Ta, W, Cr, and Ru. The third conductive part 23 includes, for example, a material having a relatively small work function.

In other words, the third conductive part 23 includes a third element. The third element is, for example, at least one selected from the group consisting of Ti, Ta, W, Cr, and Ru. The third conductive part 23 includes, for example, simple metals (e.g., Ti, Ta, W, Cr, Ru, etc.) included in the third element. Or, the third conductive part 23 may include, for example, a compound including the third element. For example, the third conductive part 23 includes a nitride of the third element (e.g., titanium nitride, tantalum nitride, tungsten nitride, chromium nitride, ruthenium nitride, etc.). Or, for example, the third conductive part 23 includes an oxide of the third element (e.g., titanium oxide, tantalum oxide, tungsten oxide, chromium oxide, ruthenium oxide, etc.). Or, the third conductive part 23 may include an alloy including the third element, or a solid solution including the third element.

The third conductive part 23 is connected to the top of the second conductive part 22. The third conductive part 23 that has a different material from the second conductive part 22 such as those described above contacts the second semiconductor region 32. The contact resistance between the second electrode 20 and the semiconductor part 30 can be controlled by the third conductive part 23.

In the example (in which the first conductivity type is the n-type), the work function of the third conductive part 23 may be less than the work function of the second conductive part 22. For example, the third conductive part 23 is made of a third conductive material having a lower work function than the second conductive part 22. For example, the third conductive part 23 is made of the same material as the first conductive part 21. The work function of the third conductive part 23 may be equal to the work function of the first conductive part 21. In the example, for example, the contact resistance can be reduced by the third conductive part 23, which has a lower work function than the second conductive part 22, contacting the second semiconductor region 32 (the first region 32s).

The material of the conductive layer 25 may be the same as the material of the first conductive part 21 or the material of the third conductive part 23.

The fourth conductive part 24 is located on the second semiconductor region 32. In other words, the second semiconductor region 32 is positioned between the fourth conductive part 24 and the first electrode 11. The direction from the second semiconductor region 32 toward the fourth conductive part 24 is along the Z-direction. The fourth conductive part 24 contacts the second semiconductor region 32 (the first region 32s). The fourth conductive part 24 may be electrically connected with the second semiconductor region 32 (the first region 32s). The fourth conductive part 24 is positioned between the insulating part 40 and the conductive layer 25 and contacts the insulating part 40 and the conductive layer 25. The fourth conductive part 24 may be electrically connected with the conductive layer 25.

The fourth conductive part 24 includes, for example, at least one selected from the group consisting of Pt, Ni, Ir, Pd, Au, and Co. The fourth conductive part 24 includes, for example, a material having a relatively large work function.

In other words, the fourth conductive part 24 includes a fourth element. The fourth element is, for example, at least one selected from the group consisting of Pt, Ni, Ir, Pd, Au, and Co. The fourth conductive part 24 includes, for example, simple metals (e.g., Pt, Ni, Ir, Pd, Au, Co, etc.) included in the fourth element. The fourth conductive part 24 may include, for example, a compound, an alloy, or a solid solution including the fourth element.

In the example (in which the first conductivity type is the n-type), the work function of the fourth conductive part 24 may be higher than the work function of the first conductive part 21. For example, the fourth conductive part 24 is made of a fourth conductive material having a higher work function than the first conductive part 21. For example, the fourth conductive part 24 is made of the same material as the second conductive part 22. The work function of the fourth conductive part 24 may be equal to the work function of the second conductive part 22.

As illustrated in FIG. 2, the first conductive part 21 includes an end portion 21u (a lower end). The second conductive part 22 also includes a first end portion 22t (the upper end) and a first other-end portion 22u (the lower end), which are Z-direction end portions. The first other-end portion 22u (the lower end) is arranged with the end portion 21u in the X-direction. At least a portion of the first other-end portion 22u is positioned between the first end portion 22t and the first electrode 11.

The first semiconductor region 31 includes a counter surface F1 that faces the first conductive part 21 and the second conductive part 22. The counter surface F1 is positioned at the bottom of the trench T1 and is along, for example, the X-Y plane. The counter surface F1 contacts the lower ends (the end portion 21u and the first other-end portion 22u) of the first and second conductive parts 21 and 22. The direction from the counter surface F1 toward the gate electrode 13 is along the X-direction.

The gate electrode 13 includes a gate end portion 13t (the upper end) and a gate other-end portion 13u (the lower end), which are Z-direction end portions. The gate other-end portion 13u is positioned between the gate end portion 13t and the first electrode 11. The gate other-end portion 13u (the lower end) may be lower than the counter surface F1. In other words, the Z-direction position of the counter surface F1 may be between the Z-direction position of the gate end portion 13t and the Z-direction position of the gate other-end portion 13u. As a result, for example, the width of the depletion layer is easily controlled by the gate electrode 13.

For example, a length L1 along the Z-direction of the second conductive part 22 contacting the second semiconductor region 32 is greater than a length L2 along the Z-direction of the third conductive part 23 contacting the second semiconductor region 32. For example, the Z-direction position of the gate end portion 13t (the upper end) is between the Z-direction position of the first end portion 22t of the second conductive part 22 and the Z-direction position of the first other-end portion 22u of the second conductive part 22. Thus, the second conductive part 22 has an overlap margin in the X-direction with the gate electrode 13 and the second semiconductor region 32 (the second region 32c). By considering the process margin, the channel region of the second semiconductor region 32 is easily depleted.

As illustrated in FIG. 2, for example, a length L3 may be greater than the length L2. The length L3 is the length along the Z-direction between the gate end portion 13t and the first end portion 22t. Or, the length L2 may be greater than the length L3. When the length L2 is long, for example, the contact resistance is easily reduced.

For example, a length L4 in the X-direction of the second conductive part 22 contacting the first semiconductor region 31 (e.g., the X-direction width of the second conductive part 22) may be greater than a length L5 in the X-direction of the first conductive part 21 contacting the first semiconductor region 31. When the length L4 is long, for example, the depletion layer of the semiconductor part 30 spreads easily. For example, the breakdown voltage can be increased. The length L5 may be greater than the length L4.

The semiconductor part 30 may include at least one selected from the group consisting of silicon (Si), nitride semiconductors (e.g., GaN, etc.), silicon carbide (SiC), and oxide semiconductors (e.g., GaO). The semiconductor part 30 is, for example, a silicon substrate. When the semiconductor part 30 includes silicon, the n-type impurity includes, for example, at least one selected from the group consisting of phosphorus, arsenic, and antimony. The p-type impurity includes, for example, boron.

The first electrode 11 includes, for example, at least one selected from the group consisting of Al, Cu, Mo, W, Ta, Co, Ru, Ti, and Pt. The gate electrode 13 and the conductive part 14 may include, for example, at least one of polysilicon or a metal. The conductive layer 26 includes, for example, at least one selected from the group consisting of Ti and TiN. The conductive layer 27 includes, for example, at least one selected from the group consisting of Al, Cu, Mo, W, Ta, Co, Ru, Ti, and Pt.

Pluralities of the first semiconductor region 31, the second semiconductor region 32, the first conductive part 21, the second conductive part 22, the third conductive part 23, and the fourth conductive part 24 may be included. Multiple trenches T1 that are arranged in the X-direction are provided, and the first conductive part 21, the second conductive part 22, and the third conductive part 23 are provided in each trench T1. Multiple first conductive parts 21, multiple second conductive parts 22, and multiple third conductive parts 23 are included in one conductive layer 25.

Pluralities of the gate electrode 13, the conductive part 14, and the insulating part 40 may be included. Multiple trenches T2 that are arranged in the X-direction are provided, and the gate electrode 13, the conductive part 14, and the insulating part 40 are provided in each trench T2. One trench T1 is located between two trenches T2. One first conductive part 21, two second conductive parts 22, and two third conductive parts 23 are located inside one trench T1.

In other words, as illustrated in FIG. 1, at least a portion of one second semiconductor region 32 and at least a portion of another second semiconductor region 32 (a semiconductor region 32b) are positioned between one gate electrode 13 and another gate electrode 13 (a gate electrode 13b). The side surface of the one second semiconductor region 32 and the side surface of the other second semiconductor region 32 are two side surfaces of mutually-facing trenches T1.

One second conductive part 22 and another second conductive part 22 (a conductive part 22b) are positioned between one second semiconductor region 32 and another second semiconductor region 32. Also, one third conductive part 23 and another third conductive part 23 (a conductive part 23b) are positioned between the one second semiconductor region 32 and the other second semiconductor region 32. The one second conductive part 22 and the one third conductive part 23 contact the side surface of the one second semiconductor region 32. The other second conductive part 22 and the other third conductive part 23 contact the side surface of the other second semiconductor region 32.

One first conductive part 21 is located between one second conductive part 22 and another second conductive part 22. The one first conductive part 21 contacts the one second conductive part 22 and the other second conductive part 22. The one first conductive part 21, the one second conductive part 22, and the other second conductive part 22 contact the bottom of one trench T1 (one first semiconductor region 31).

One fourth conductive part 24 is located on one second semiconductor region 32; and another fourth conductive part (a conductive part 24b) is located on another second semiconductor region 32.

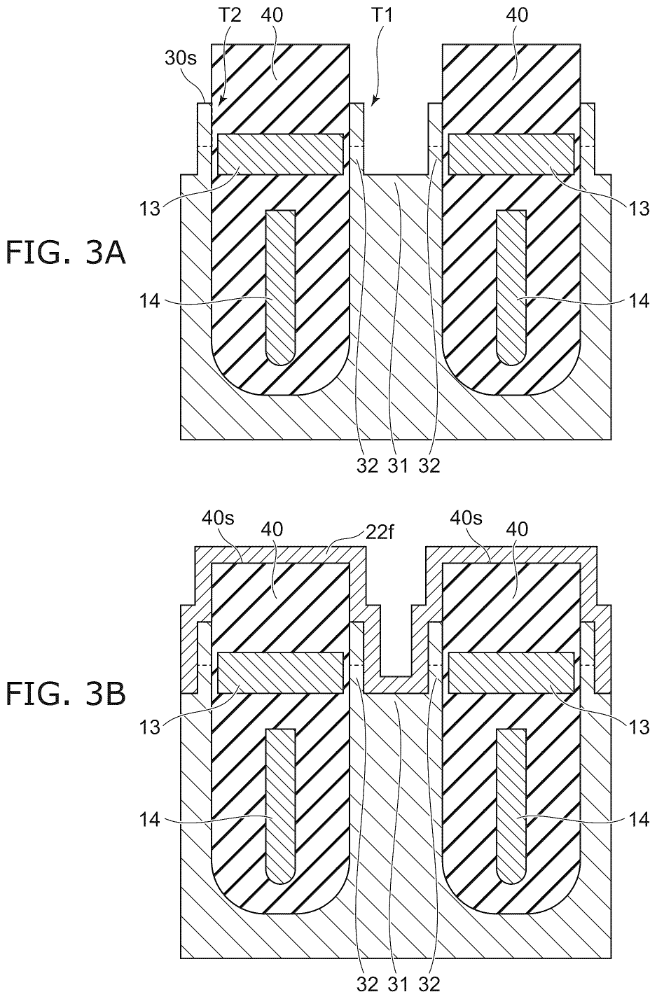

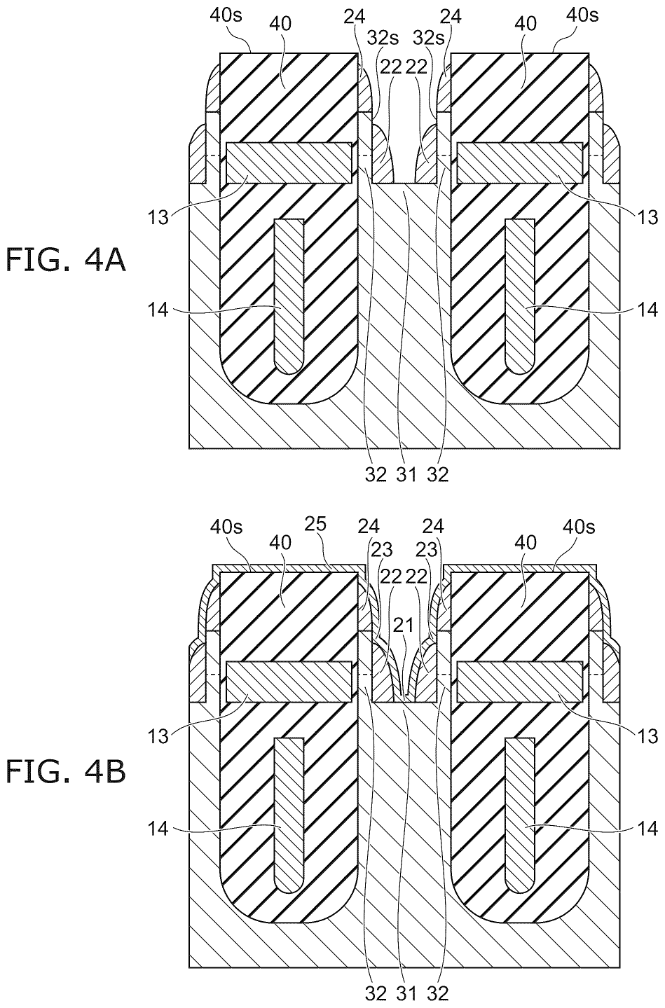

FIGS. 3A, 3B, 4A, and 4B are schematic cross-sectional views illustrating a method for manufacturing the semiconductor device according to the embodiment. These drawings illustrate some of the manufacturing processes of the semiconductor device 100.

As illustrated in FIG. 3A, the trench T2 is provided in the surface 30s of the semiconductor part 30. The insulating part 40, the conductive part 14, and the gate electrode 13 are filled into the trench T2. The trench T1 is provided in the surface 30s of the semiconductor part 30. The first semiconductor region 31 and the second semiconductor region 32 are formed thereby.

As illustrated in FIG. 3B, a conductive film 22f that is used to form the second conductive part 22 and the fourth conductive part 24 is formed on the semiconductor part 30 and the insulating part 40. The conductive film 22f contacts the end surface 40s of the insulating part 40, the side surface and upper end of the second semiconductor region 32, and the first semiconductor region 31.

As illustrated in FIG. 4A, for example, a portion of the conductive film 22f is removed by reactive ion etching. As a result, the second conductive part 22 and the fourth conductive part 24 are formed, and the end surface 40s of the insulating part 40, the side surface of the first region 32s of the second semiconductor region 32, and a portion of the first semiconductor region 31 are exposed.

As illustrated in FIG. 4B, the continuous conductive layer 25 is formed on the first semiconductor region 31, the second conductive part 22, the fourth conductive part 24, and the insulating part 40. The conductive layer 25 contacts the first semiconductor region 31 and the second semiconductor region 32 (the first region 32s) exposed in FIG. 4A. The first conductive part 21 and the third conductive part 23 are formed thereby. The conductive layer 25 covers the end surface 40s of the insulating part 40 and contacts the end surface 40s.

Thus, the first conductive part 21 and the third conductive part 23 are included in the conductive layer 25 covering the second conductive part 22, the fourth conductive part 24, and the insulating part 40. By forming the conductive layer 25 to cover the second conductive part 22, the first conductive part 21 and the third conductive part 23 can be formed.

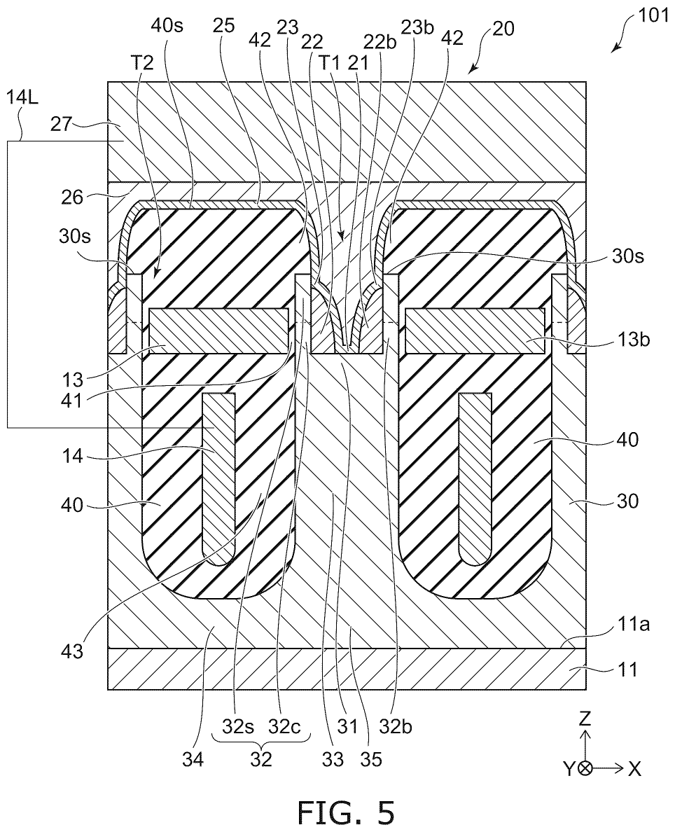

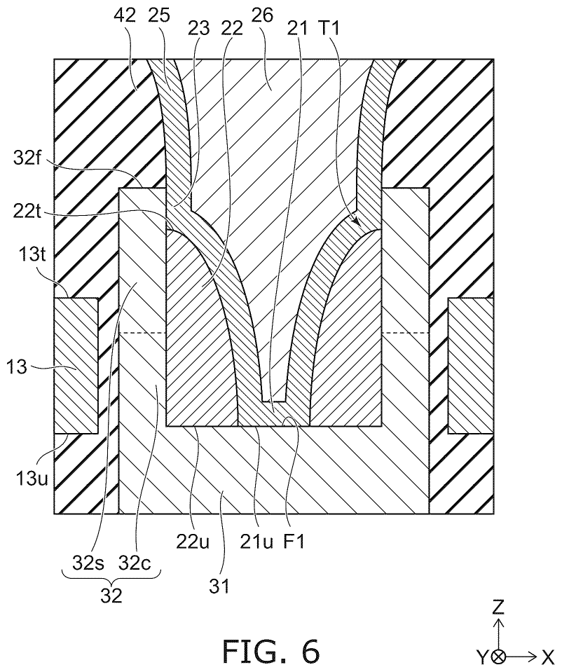

FIGS. 5 and 6 are schematic cross-sectional views illustrating a semiconductor device according to an embodiment.

FIG. 6 is an enlarged illustration of the periphery of the first conductive part 21 of FIG. 5.

In the semiconductor device 101 illustrated in FIGS. 5 and 6, the fourth conductive part 24 is not provided on the second semiconductor region 32; and the insulating part 40 includes a second insulating region 42.

The second insulating region 42 is positioned on the second semiconductor region 32. In other words, the second semiconductor region 32 is positioned between the second insulating region 42 and the first electrode 11. The direction from the second semiconductor region 32 toward the second insulating region 42 is along the Z-direction.

For example, as illustrated in FIG. 6, the second semiconductor region 32 includes an upper surface 32f (the upper end). For example, the upper surface 32f faces the Z-direction and extends along the X-Y plane. The second insulating region 42 contacts the upper surface 32f of the second semiconductor region 32. The entire upper surface 32f may be covered with the second insulating region 42. The upper surface 32f may not contact the second electrode 20. A portion of the conductive layer 25 is located on the second insulating region 42 and contacts the second insulating region 42.

Otherwise, a description similar to that of the semiconductor device 100 described above is applicable to the configuration of the semiconductor device 101 illustrated in FIGS. 5 and 6. In the semiconductor device 101 as well, similarly to the semiconductor device 100, a more appropriate forward voltage of the body diode can be obtained. For example, the forward voltage can be reduced. Also, the contact resistance between the second electrode 20 and the semiconductor part 30 can be reduced.

When the fourth conductive part 24 that contacts the upper surface of the second semiconductor region 32 is included as in the semiconductor device 100 illustrated in FIG. 1, etc., a path is formed in which carriers flow between the fourth conductive part 24 and the semiconductor part 30 via the upper surface of the second semiconductor region 32. At this time, for example, contact resistance is generated between the fourth conductive part 24 and the upper surface of the second semiconductor region 32. For example, the fourth conductive part 24 has a high work function; and a high contact resistance is generated. On the other hand, in the semiconductor device 101 illustrated in FIG. 5, etc., the second insulating region 42 is included; and contact between the second electrode 20 and the upper surface 32f of the second semiconductor region 32 is suppressed. The flow of carriers via the upper surface 32f of the second semiconductor region 32 is suppressed, and the contact is easily adjusted. For example, the contact resistance can be reduced.

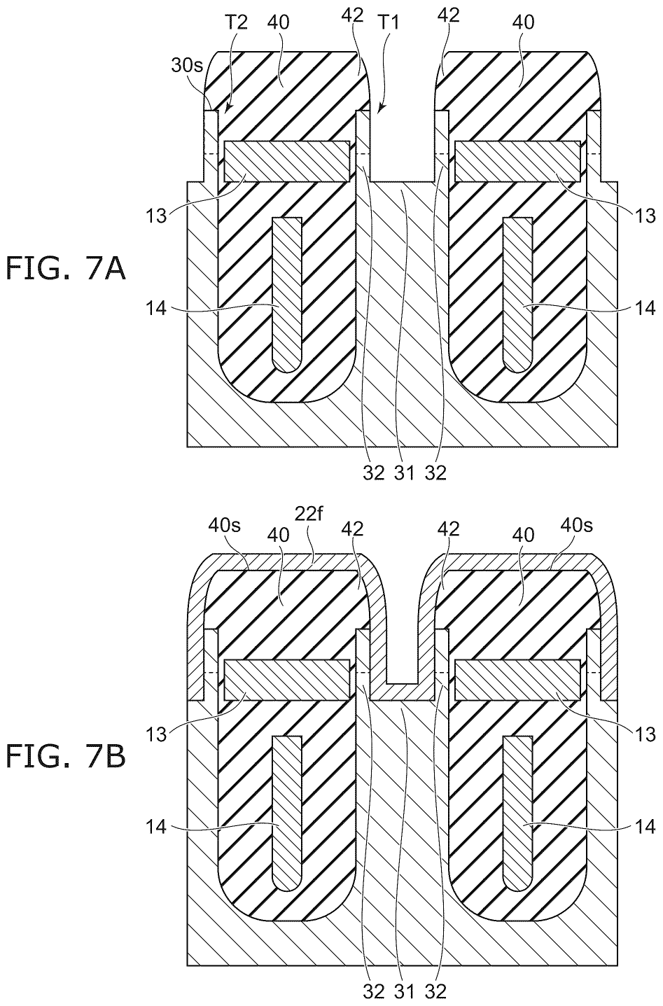

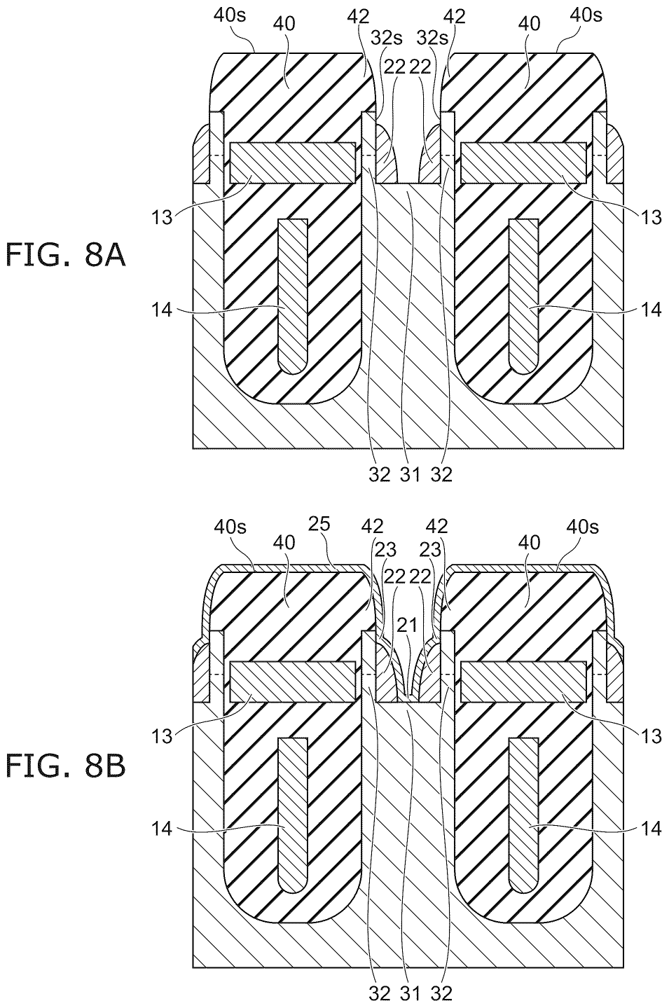

FIGS. 7A, 7B, 8A, and 8B are schematic cross-sectional views illustrating a method for manufacturing the semiconductor device according to the embodiment. These drawings illustrate some of the manufacturing processes of the semiconductor device 101.

As illustrated in FIG. 7A, the trench T2 is provided in the surface 30s of the semiconductor part 30. The insulating part 40, the conductive part 14, and the gate electrode 13 are filled into the trench T2. A portion of the insulating part 40 (the portion used to form the second insulating region 42) is located on a portion of the semiconductor part 30 (the portion used to form the second semiconductor region 32). Also, the trench T1 is provided in the surface 30s of the semiconductor part 30. The first semiconductor region 31 and the second semiconductor region 32 are formed thereby. The second insulating region 42 that is positioned on the second semiconductor region 32 is formed.

As illustrated in FIG. 7B, the conductive film 22f that is used to form the second conductive part 22 and the fourth conductive part 24 is formed on the semiconductor part 30 and the insulating part 40. The conductive film 22f contacts the end surface 40s of the insulating part 40, the second insulating region 42, the side surface of the second semiconductor region 32, and the first semiconductor region 31.

As illustrated in FIG. 8A, for example, a portion of the conductive film 22f is removed by reactive ion etching. As a result, the second conductive part 22 is formed; and the end surface 40s of the insulating part 40, the second insulating region 42, the side surface of the first region 32s of the second semiconductor region 32, and a portion of the first semiconductor region 31 are exposed.

As illustrated in FIG. 8B, the continuous conductive layer 25 is formed on the first semiconductor region 31, the second conductive part 22, and the insulating part 40. The conductive layer 25 contacts the first semiconductor region 31 and the second semiconductor region 32 (the first region 32s) exposed in FIG. 8A. The first conductive part 21 and the third conductive part 23 are formed thereby. The conductive layer 25 covers the end surface 40s of the insulating part 40 and the second insulating region 42 and contacts the end surface 40s and the second insulating region 42.

Thus, the first conductive part 21 and the third conductive part 23 are included in the conductive layer 25 covering the second conductive part 22 and the second insulating region 42. The first conductive part 21 and the third conductive part 23 can be formed by forming the conductive layer 25 to cover the second conductive part 22.

The embodiments may include the following configurations (for example, technical proposals).

Configuration 1. A semiconductor device, comprising:
a first electrode;
a first conductive part, a direction from the first electrode toward the first conductive part being along a first direction, the first conductive part including at least one of a metal, a metal oxide, or a metal nitride, the at least one of the metal, the metal oxide, or the metal nitride including at least one selected from the group consisting of Ti, Ta, W, Cr, and Ru;
a semiconductor part of a first conductivity type, the semiconductor part including a first semiconductor region and a second semiconductor region, at least a portion of the first semiconductor region being positioned between the first conductive part and the first electrode, the first conductive part having a Schottky contact with the first semiconductor region, a direction from the first conductive part toward the second semiconductor region being along a second direction crossing the first direction;
a second conductive part having a Schottky contact with the second semiconductor region, the second conductive part including at least one selected from the group consisting of Pt, Ni, Ir, Pd, Au, and Co, at least a portion of the second conductive part being positioned between the first conductive part and the second semiconductor region;
a gate electrode, at least a portion of the second semiconductor region being positioned between the gate electrode and the second conductive part; and
an insulating part including a first insulating region, the first insulating region being located between the gate electrode and the second semiconductor region.
   Configuration 2. The device according to Configuration 1, further comprising:
a third conductive part contacting the second semiconductor region, the third conductive part including at least one of a metal, a metal oxide, or a metal nitride, the at least one of the metal, the metal oxide, or the metal nitride including at least one selected from the group consisting of Ti, Ta, W, Cr, and Ru,
the second conductive part being positioned between the third conductive part and the first semiconductor region.
   Configuration 3. The device according to Configuration 2, wherein
the second semiconductor region includes:
   a first region; and
   a second region positioned between the first region and the first electrode,
a first-conductivity-type impurity concentration in the first region is greater than a first-conductivity-type impurity concentration in the second region, and
the third conductive part contacts the first region.
   Configuration 4. The device according to Configuration 2 or 3, wherein
a length along the first direction of the second conductive part contacting the second semiconductor region is greater than a length along the first direction of the third conductive part contacting the second semiconductor region.
   Configuration 5. The device according to Configuration 4, wherein
the second conductive part includes a first end portion and a first other-end portion,
the first other-end portion is positioned between the first end portion and the first electrode in the first direction,
the gate electrode includes a gate end portion and a gate other-end portion,
the gate other-end portion is positioned between the gate end portion and the first electrode in the first direction, and
a position in the first direction of the gate end portion is between a position in the first direction of the first end portion and a position in the first direction of the first other-end portion.
   Configuration 6. The device according to any one of Configurations 2 to 5, wherein
the first conductive part and the third conductive part are included in a conductive layer covering the second conductive part.
   Configuration 7. The device according to Configuration 6, wherein
the conductive layer contacts an end surface in the first direction of the insulating part.
   Configuration 8. The device according to any one of Configurations 1 to 5, further comprising:
a fourth conductive part including at least one selected from the group consisting of Pt, Ni, Ir, Pd, Au, and Co,
the second semiconductor region being positioned between the fourth conductive part and the first electrode and contacting the fourth conductive part.
   Configuration 9. The device according to Configuration 8, wherein
the first conductive part is included in a conductive layer covering the second conductive part and the fourth conductive part.
   Configuration 10. The device according to any one of Configurations 1 to 5, wherein
the insulating part further includes a second insulating region, and
the second semiconductor region is positioned between the second insulating region and the first electrode and contacts the second insulating region.
   Configuration 11. The device according to Configuration 10, wherein
the first conductive part is included in a conductive layer covering the second conductive part and the second insulating region.
   Configuration 12. The device according to any one of Configurations 1 to 11, wherein
a work function of the first conductive part is less than a work function of the second conductive part.
   Configuration 13. The device according to any one of Configurations 2 to 7, wherein
a work function of the third conductive part is less than a work function of the second conductive part.
   Configuration 14. The device according to Configuration 8 or 9, wherein
a work function of the fourth conductive part is higher than a work function of the first conductive part.
   Configuration 15. The device according to any one of Configurations 1 to 14, wherein
a portion of the first semiconductor region is positioned between the second conductive part and the first electrode, and
the second conductive part contacts the portion of the first semiconductor region.
   Configuration 16. The device according to Configuration 15, wherein
a length in the second direction of the second conductive part contacting the first semiconductor region is greater than a length in the second direction of the first conductive part contacting the first semiconductor region.
   Configuration 17. The device according to any one of Configurations 1 to 16, further comprising:
a conductive region,
the semiconductor part including a third semiconductor region positioned between the first semiconductor region and the first electrode,
a direction from the conductive region toward the third semiconductor region being along the second direction,
the insulating part including a third insulating region located between the third semiconductor region and the conductive region.
   Configuration 18. The device according to any one of Configurations 1 to 17, wherein
the first semiconductor region includes a counter surface facing the first conductive part, and
a direction from the counter surface toward the gate electrode is along the second direction.
   Configuration 19. The device according to any one of Configurations 1 to 18, wherein
a plurality of the gate electrodes, a plurality of the second semiconductor regions, and a plurality of the second conductive parts are included,
at least a portion of one of the second semiconductor regions and at least a portion of another of the second semiconductor regions are positioned between one of the gate electrodes and another of the gate electrodes,
one of the second conductive parts and another of the second conductive parts are positioned between the one of the second semiconductor regions and the other of the second semiconductor regions, and
the first conductive part is positioned between the one of the second conductive parts and the other of the second conductive parts.

Information that relates to the configurations of the semiconductor regions, etc., in the embodiments is obtained by, for example, electron microscopy, etc. Information that relates to the impurity concentrations of the materials and semiconductor regions is obtained by, for example, EDX (Energy Dispersive X-ray Spectroscopy), SIMS (Secondary Ion Mass Spectrometry), etc.

According to embodiments, a semiconductor device can be provided in which a more appropriate forward voltage of a body diode can be obtained.

In the specification, “nitride semiconductor” includes all compositions of semiconductors of the chemical formula BₓIn_{y}Al_{z}Ga_{1-x-y-z}N (0≤x≤1, 0≤y≤1, 0≤z≤1, and x+y+z≤1) for which the composition ratios x, y, and z are changed within the ranges respectively. “Nitride semiconductor” further includes Group V elements other than N (nitrogen) in the chemical formula above, various elements added to control various properties such as the conductivity type and the like, and various elements included unintentionally.

In this specification, being “electrically connected” includes not only the case of being connected in direct contact, but also the case of being connected via another conductive member, etc.

In the specification of the application, “perpendicular” refers to not only strictly perpendicular but also includes, for example, the fluctuation due to manufacturing processes, etc. It is sufficient to be substantially perpendicular.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in semiconductor devices from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a first conductive part, a direction from the first electrode toward the first conductive part being along a first direction, the first conductive part including at least one of a metal, a metal oxide, or a metal nitride, the at least one of the metal, the metal oxide, or the metal nitride including at least one selected from the group consisting of Ti, Ta, W, Cr, and Ru;
a semiconductor part of a first conductivity type, the semiconductor part including a first semiconductor region and a second semiconductor region, at least a portion of the first semiconductor region being positioned between the first conductive part and the first electrode, the first conductive part having a Schottky contact with the first semiconductor region, a direction from the first conductive part toward the second semiconductor region being along a second direction crossing the first direction;
a second conductive part having a Schottky contact with the second semiconductor region, the second conductive part including at least one selected from the group consisting of Pt, Ni, Ir, Pd, Au, and Co, at least a portion of the second conductive part being positioned between the first conductive part and the second semiconductor region;
a gate electrode, at least a portion of the second semiconductor region being positioned between the gate electrode and the second conductive part; and
an insulating part including a first insulating region, the first insulating region being located between the gate electrode and the second semiconductor region.

2. The device according to claim 1, further comprising:
a third conductive part contacting the second semiconductor region, the third conductive part including at least one of a metal, a metal oxide, or a metal nitride, the at least one of the metal, the metal oxide, or the metal nitride including at least one selected from the group consisting of Ti, Ta, W, Cr, and Ru,
the second conductive part being positioned between the third conductive part and the first semiconductor region.

3. The device according to claim 2, wherein
the second semiconductor region includes:
a first region; and
a second region positioned between the first region and the first electrode,
a first-conductivity-type impurity concentration in the first region is greater than a first-conductivity-type impurity concentration in the second region, and
the third conductive part contacts the first region.

4. The device according to claim 2, wherein
a length along the first direction of the second conductive part contacting the second semiconductor region is greater than a length along the first direction of the third conductive part contacting the second semiconductor region.

5. The device according to claim 4, wherein
the second conductive part includes a first end portion and a first other-end portion,
the first other-end portion is positioned between the first end portion and the first electrode in the first direction,
the gate electrode includes a gate end portion and a gate other-end portion,
the gate other-end portion is positioned between the gate end portion and the first electrode in the first direction, and
a position in the first direction of the gate end portion is between a position in the first direction of the first end portion and a position in the first direction of the first other-end portion.

6. The device according to claim 2, wherein
the first conductive part and the third conductive part are included in a conductive layer covering the second conductive part.

7. The device according to claim 6, wherein
the conductive layer contacts an end surface in the first direction of the insulating part.

8. The device according to claim 1, further comprising:
a fourth conductive part including at least one selected from the group consisting of Pt, Ni, Ir, Pd, Au, and Co,
the second semiconductor region being positioned between the fourth conductive part and the first electrode and contacting the fourth conductive part.

9. The device according to claim 8, wherein
the first conductive part is included in a conductive layer covering the second conductive part and the fourth conductive part.

10. The device according to claim 1, wherein
the insulating part further includes a second insulating region, and
the second semiconductor region is positioned between the second insulating region and the first electrode and contacts the second insulating region.

11. The device according to claim 10, wherein
the first conductive part is included in a conductive layer covering the second conductive part and the second insulating region.

12. The device according to claim 1, wherein
a work function of the first conductive part is less than a work function of the second conductive part.

13. The device according to claim 2, wherein
a work function of the third conductive part is less than a work function of the second conductive part.

14. The device according to claim 8, wherein
a work function of the fourth conductive part is higher than a work function of the first conductive part.

15. The device according to claim 1, wherein
a portion of the first semiconductor region is positioned between the second conductive part and the first electrode, and
the second conductive part contacts the portion of the first semiconductor region.

16. The device according to claim 15, wherein
a length in the second direction of the second conductive part contacting the first semiconductor region is greater than a length in the second direction of the first conductive part contacting the first semiconductor region.

17. The device according to claim 1, further comprising:
a conductive region,
the semiconductor part including a third semiconductor region positioned between the first semiconductor region and the first electrode,
a direction from the conductive region toward the third semiconductor region being along the second direction,
the insulating part including a third insulating region located between the third semiconductor region and the conductive region.

18. The device according to claim 1, wherein
the first semiconductor region includes a counter surface facing the first conductive part, and
a direction from the counter surface toward the gate electrode is along the second direction.

19. The device according to claim 1, wherein
a plurality of the gate electrodes, a plurality of the second semiconductor regions, and a plurality of the second conductive parts are included,
at least a portion of one of the second semiconductor regions and at least a portion of another of the second semiconductor regions are positioned between one of the gate electrodes and another of the gate electrodes,
one of the second conductive parts and another of the second conductive parts are positioned between the one of the second semiconductor regions and the other of the second semiconductor regions, and
the first conductive part is positioned between the one of the second conductive parts and the other of the second conductive parts.
